(19) United States
(12) Patent Application Publication
(10) Pub. No.: US 2006/0161823 A1
(43) Pub. Date: Jul. 20, 2006

(54) Disk array system configuring a logical disk drive having a redundancy function

(75) Inventor: Hiroyuki Sato, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 11/333,328

(22) Filed: Jan. 18, 2006

(30) Foreign Application Priority Data
Jan. 19, 2005 (JP) 2005-011303

(51) Int. Cl. G11C 29/00

(52) U.S. Cl. 714/710

(57) ABSTRACT

A disk array system includes a plurality of physical disks (10 to 25) configuring a logical disk (101 to 104) having a redundancy function, and a plurality of spare disks (50 to 53) for storing recovered data recovered from the physical disks (10 to 25) by the redundancy function upon occurring of a failure of one of the logical disks (10 to 25). A spare disk controller (40) writes the recovered data into the spare disks (50 to 53) in parallel for a high-speed redundancy recovery.

### BACKGROUND OF THE INVENTION

(a) Field of the Invention

The present invention relates to a disk array system configuring a logical disk drive having a redundancy function, and more particularly, to a disk array system including a plurality of physical disk drives used as a single logical disk drive having a redundancy configuration. The present invention also relates to a method for use in such a disk array system.

(b) Description of the Related Art

A disk array system including a plurality of physical disk drives used as a single logical disk drive is known in the art. Hereinafter, a disk drive including a disk or disks is referred to as simply “disk” in this text. In the disk array system, data are generally stored in a redundancy technique for achieving no loss of data. Examples of this disk array system include a RAID (Redundant Array of Independent Disks) system. In the RAID system having a redundancy configuration, if a failure occurs in one of the physical disks in the disk array system and thus data cannot be read from the failed physical disk, the data stored in the failed physical disk are recovered from the data stored in the other disks in the disk array system.

In the disk array system having a redundancy configuration, if a failure occurs in one of the physical disks, the data itself stored in the failed physical disk can be read from the other physical disks, as described above. However, the redundancy configuration in the system is lost after the failure. For solving this problem, the disk array system may be provided with one or more physical spare disks in addition to the normal physical disks configuring the logical disk having a redundancy function. In such a disk array system, if a failure occurs in one of the normal physical disks to loose the redundancy function, the data stored in the failed physical disk is recovered from the other physical disks, and then stored in the physical spare disk to recover the redundancy function without power-off of the computer system. This function is known as a hot-swap function.

The technique for recovering the redundancy function by using the spare disk as described above is described in Patent Publications JP-2002-297322A and JP-2003-186630A, for example. In JP-2002-297322A, the disk array system includes a plurality of physical disks having a 72-GB capacity each and configuring a single logical disk, and two spare disks each having a 36-GB capacity. If one of the physical disks is failed, the data recovered from the remaining physical disks is divided into two 36-GB data blocks, and the divided data blocks each including 36-GB data are stored in the respective spare disks for recovery of the redundancy. This technique allows a plurality of physical disks each having a smaller data capacity to hot-swap a logical disk including a plurality of larger-capacity physical disks.

In JP-2003-186630A, a physical disk having a larger capacity is used as a spare disk. For example, the whole data area of the spare disk having a 72-GB capacity is divided into a plurality of sub-areas including two 18-GB sub-areas, and a 36-GB sub-area. Each of the 18-GB sub-areas is used as a spare data area for a logical disk including a plurality of 18-GB physical disks, and the 36-GB sub-area is used as a spare data area for another logical disk including a plurality of 36-GB physical disks. This technique allows a larger-capacity physical disk to hot-swap a plurality of logical disks each having a smaller capacity.

### DISCLOSURE OF THE INVENTION

(a) Problem to be Solved by the Invention

The time length needed for the recovery of the redundancy in the logical disk by using the hot-swap function depends on the performance, i.e., writing data rate, of the physical disk having a minimum writing data rate among all the physical disks including the normal physical disks and the physical spare disks. In general, a physical disk having a higher writing data rate is more expensive. Thus, for achieving a high-speed recovery of redundancy in the conventional logical disk, it is necessary to employ a spare disk having a higher writing data rate although the spare disk is not used in a normal state of the logical disk, resulting in waste of resources. In short, there is a problem in that a spare disk having a higher writing data rate to achieve a high-speed recovery of the redundancy in the disk array system incurs a larger cost for the disk array system.

It is an object of the present invention to provide a disk array system achieving a higher-speed recovery of the redundancy in a logical disk after occurring of a failure in the logical disk, while using inexpensive spare disks.

It is another object of the present invention to provide a method for hot-swapping in a disk array system such as described above.

(b) Means for Solving the Invention

The present invention provides a disk array system including: a plurality of first physical disks configuring a logical disk having a redundancy function; a plurality of second physical disks operating as a spare disks for the first physical disks; and a spare disk controller for writing recovered data into at least two of the second physical disks in parallel, the recovered data being recovered from the first physical disks by the redundancy function upon occurring of a failure in the logical disk.

The present invention also provides a method for hot-swapping in a disk array system, including: configuring a logical disk having a redundancy function from a plurality of first physical disks; recovering data from the first physical disks by using the redundancy function upon occurring of a failure in the logical disk; and writing the recovered data into at least two of said second physical disks in parallel.

In accordance with the disk array system and the method of the present invention, the writing of the recovered data into a plurality of second physical disks in parallel reduces the time length needed for writing the recovered data and thus reduces the time length between occurring of the failure and recovery of the redundancy function, thereby improving the reliability of the disk array system.

The above and other objects, features and advantages of the present invention will be more apparent from the following description, referring to the accompanying drawings.

### BRIEF DESCRIPTION OF THE DRAWINGS

FIG. 1 is a block diagram of a disk array system according to a first embodiment of the present invention.

FIG. 2 is a block diagram of a disk array system according to a second embodiment of the present invention.

FIG. 3 is a table stored in the priority table memory for tabulating the logical disks and the priority of the logical disks in the data recovery.

FIGS. 4A and 4B are block diagrams of a logical spare disk in which a plurality of physical spare disks are allocated with a block area.

### BEST MODE FOR CARRYING OUT THE INVENTION

Now, the present invention is more specifically described with reference to accompanying drawings, wherein similar constituent elements are designated by similar reference numerals throughout the drawings.

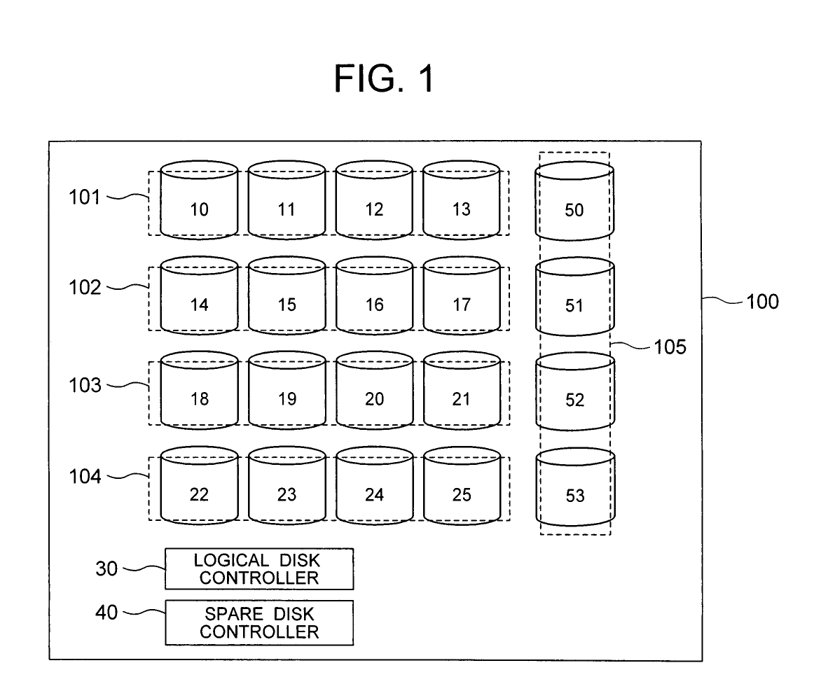

FIG. 1 shows a block diagram of a disk array system according to a first embodiment of the present invention. The disk array system generally designated by numeral 100 includes a plurality (16) of physical disks (first physical disks) 10 to 25, a plurality (4) of physical disks (second physical disks) 50 to 53, a logical disk controller 30, and a spare disk controller 40. The first logical disks 10 to 25 are used as main disks in the disk array system 100. The second logical disks 50 to 53 are used as spare disks. The second logical disks 50 to 53 have a lower read/write data rate compared to the first logical disks 10 to 25, and thus are less expensive.

The sixteen first physical disks 10 to 25 configure four logical disks 101 to 104. More specifically, the logical disk controller 30 allows the physical disks 10 to 13 to configure a first logical disk 101, allows the physical disks 14 to 17 to configure a second logical disk 102, allows the physical disks 18 to 21 to configure a third logical disk 103, and allows the physical disks 22 to 25 to configure a fourth logical disk 104. The logical disk controller 30 reads/writes data from/to the logical disks 101 to 104. The logical disks 101 to 104 have a redundancy function by using parity data, and thus incur no loss of data even if one of the physical disks configuring each of the logical disks 101 to 104 is failed.

The logical disk controller 30 configures each of the logical disks 101 to 104 as a RAID5, for example. When the logical disk controller 30 is to store a data file in the logical disk 101, for example, the logical disk controller 30 divides the data file into three data blocks, and creates a parity data block from the three data blocks. The logical disk controller 30 then writes the four data blocks including the original three data blocks and the parity data block into the respective physical disks 10 to 13 of the logical disk 101 in parallel. The parity data block may be stored in any of the four physical disks 10 to 13 upon writing of a data file, whereby the parity data blocks of a plurality of data files are distributed among the four physical disks 10 to 13. If one of the physical disks 10 to 13 is failed and thus one of the four data blocks of all the data files cannot be read from the failed physical disk, all the data files stored in the logical disk 101 can be recovered from the remaining three physical disks 10 to 13 other than the failed physical disk.

The spare disk controller 40 configures a logical spare disk 105 from the four physical disks 50 to 53, and reads/writes data from/to the logical spare disk 105. The spare disk controller 40 configures the logical spare disk 105 as a RAID5 system, and reads/writes data from/to the physical disks 50 to 53 in parallel, whereby the logical spare disk 105 has a higher read/write data rate compared to the individual physical disks 50 to 53 configuring the logical spare disk 105.

If any one of the physical disks in one of the logical disks 101 to 104 is failed, the logical disk controller 30 recovers the stored data from the three physical disks other than the failed physical disk. The logical disk controller 30 writes the data thus recovered into the logical spare disk 105 via the spare disk controller 40. Thereafter, the logical disk controller 30 configures the logical disk 101 by using the three physical disks other than the failed disk and the logical spare disk 105.

If one of the physical disks 10 to 13 in the logical disk 105, e.g., if the physical disk 11 is failed, the logical disk controller 30 recovers the data stored in the failed physical disk 11 from the data stored in the physical disks 10, 12 and 13, and writes the recovered data into logical spare disk 105 via the spare disk controller 40. The spare disk controller 40 divides the recovered data into four data blocks, and writes the four data blocks into the respective physical spare disks 50 to 53 of the logical spare disk 105 in parallel. Thereafter, the logical disk controller 30 configures the logical disk 101 from the physical disks 10, 12 and 13 and the logical spare disk 105, until the failed physical disk 11 is replaced by a new physical disk.

In the present embodiment, the spare disk controller 40 reads/writes data from/to the physical spare disks 50 to 53 in parallel. Thus, the read/write data rate of the logical spare disk 105 can be set comparable to the read/write data rate of the physical disks 10 to 25 configuring the logical disks 101 to 104, even though the physical disks 50 to 53 configuring the logical spare disk 105 have read/write data rate lower than the read/write data rate of the physical disks 10 to 25. Accordingly, low-cost physical disks may be used as the physical spare disks 50 to 53 without involving a larger time length for the recovery of the redundancy in the logical disks 101 to 104. The smaller time length needed for the recovery of the redundancy improves the reliability of the disk array system 100.

In the present embodiment, since the spare disk controller 40 configures a RAID system in the logical spare disk 105 including the plurality of physical disks 50 to 53, the spare disk controller 40 is capable of controlling the logical spare disk 105 in the level of the RAID configured. Thus, the physical spare disks 50 to 53 need not have the same read/write characteristic, and may have different read/write data rates. In addition, since the spare disk controller 40 is capable of controlling the capacity of the logical spare disk 105 configured by the physical disks 50 to 53, the physical spare disks 50 to 53 each may have a capacity different from the capacity of the physical disks 10 to 25 configuring the logical disks 101 to 104.

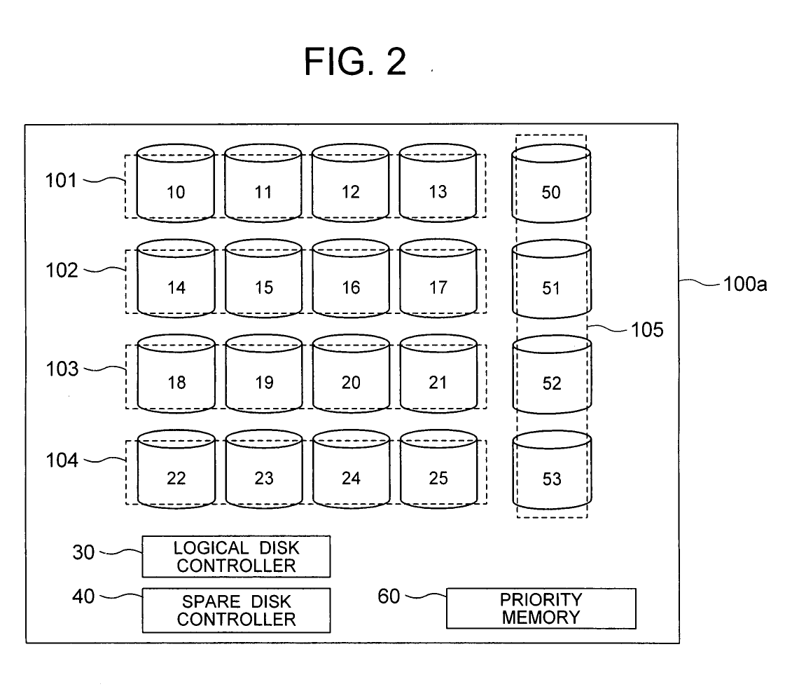

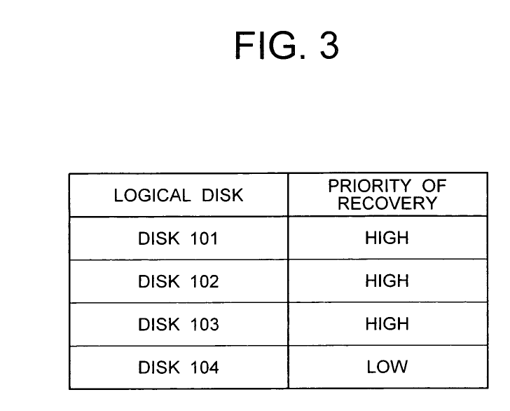

FIG. 2 shows a disk array system according to a second embodiment of the present invention. The disk array system 100a of the present embodiment is similar to the first embodiment except that the logical disks 101 to 104 have respective recovery priorities stored in a recovery priority memory (priority storage section) 60 in the present embodiment. FIG. 3 exemplifies a table of the recovery priority of the logical disks 101 to 104. A logical disk for which a high-speed redundancy recovery is needed has a “High” priority, whereas another logical disk for which a high-speed redundancy recovery is not need has a “Low” priority.

If a failure occurs in one of the physical disks in any of the logical disks 101 to 104, the spare disk controller 40 refers to the recovery priority memory 60 to retrieve the priority of the logical disk including the failed physical disk. The spare disk controller 40 then allocates a block area in the logical spare disk 105 for the recovered data based on the priority of the failed logical disk. The spare disk controller 40 then uses the allocated block area in the logical spare disk 105 to recover the redundancy.

If the failed logical disk has a “High” priority, the spare disk controller 40 allocates the block area in the logical spare disk 105 such that the spare disk controller 40 stores the recovered data into the physical spare disks 50 to 53 in parallel, for achieving a high-speed redundancy recovery. On the other hand, if the failed logical disk has a “Low” priority, the spare disk controller 40 selects one of the physical spare disks 50 to 53 having a largest free space among the physical spare disks 50 to 53, and allocates a block area in the physical spare disk thus selected to recover the redundancy.

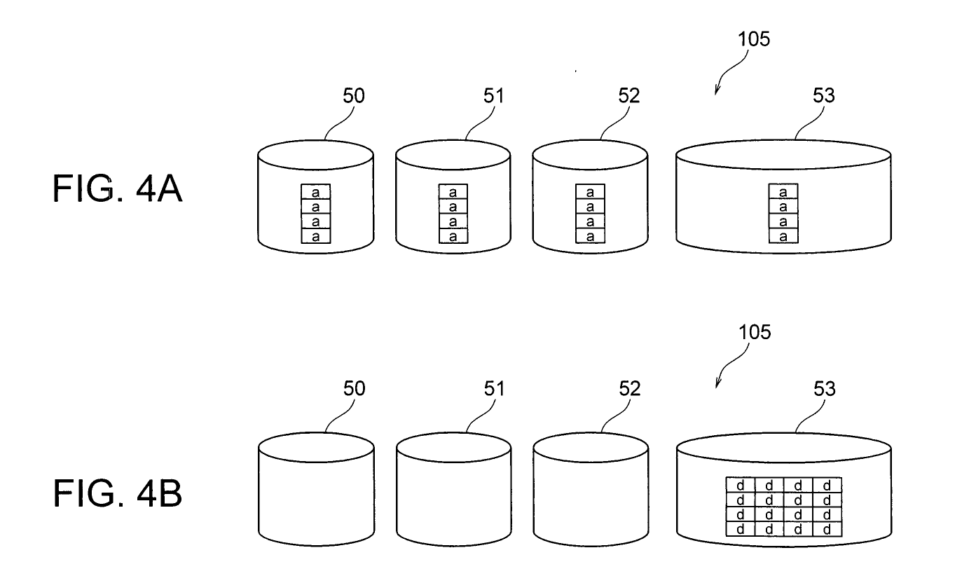

FIGS. 4A and 4B show the block area allocated in the logical spare disk 105 for the redundancy recovery. If the spare disk controller 40 recovers the redundancy for the logical disk 101, for example, having a “High” priority, the spare disk controller 40 allocates a block area “a” in each of the physical spare disks 50 to 53, and stores the recovered data in the block area “a” of the physical spare disks 50 to 53 in parallel. In this case, the parallel writing of the recovered data provides a high-speed redundancy recovery, and the parallel reading of the data from the physical spare disks 50 to 53 provides a higher-speed operation of the disk array system 100 during the use of the logical spare disk 105.

On the other hand, if the spare disk controller 40 recovers the redundancy for the logical disk 104, for example, having a “Low” priority, the spare disk controller 40 allocates a block area “d” in the physical spare disk 53 having a largest free space among the physical spare disks 50 to 53, and stores the recovered data in the block area “d” of the physical spare disk 53. In this case, the time length needed for the redundancy recovery is determined based on the writing data rate of the physical disk 53, whereby the speed of the redundancy recovery is lower compared to the case of the “High” priority. This is accepted in the disk array system 100 because of the logical disk 104 having a “Low” priority.

In the present embodiment, for the logical disk having a “High” priority, the recovered data is allocated to the plurality of physical spare disks 50 to 53 to recover the redundancy at a higher speed. On the other hand, for the logical disk having a “Low” priority, the recovered data is allocated to the physical spare disk 53 having a largest free space. This provides an efficient use of the capacity of the physical spare disk. The latter operation is particularly effective in the case where the physical spare disks 50 to 53 have different storage capacities, or where a new physical spare disk such as 53 is added in the logical spare disk 105.

In the present embodiment, the priority is set at two different levels, “High” or “Low”; however, the priority may be set at three levels, such as “High”, “Medium” and “Low”, or more than three levels. If the priority is set at three levels, for example, the logical spare disk 105 uses four physical spare disks 50 to 53 for the logical disk having a “High” priority, uses two physical spare disks for the logical disk having a “Medium” priority, and uses a single physical spare disk for the logical disk having a “Low” priority.

Since the above embodiments are described only for examples, the present invention is not limited to the above embodiments and various modifications or alterations can be easily made therefrom by those skilled in the art without departing from the scope of the present invention.

What is claimed is:

1. A disk array system comprising:
a plurality of first physical disks configuring a logical disk having a redundancy function;
a plurality of second physical disks operating as a spare disks for said first physical disks; and
a spare disk controller for writing recovered data into at least two of said second physical disks in parallel, said recovered data being recovered from said first physical disks by said redundancy function upon occurring of a failure in said logical disk.

2. The disk array system according to claim 1, wherein said second physical disks have a writing data rate lower than a writing data rate of said first physical disks.

3. The disk array system according to claim 2, wherein said spare disk controller writes said recovered data into said second physical disks in parallel at a writing data rate higher than said writing data rate of said second physical disks.

4. The disk array system according to claim 1, wherein said first physical disks configure a plurality of said logical disk.

5. The disk array system according to claim 4, further comprising a priority storage section for storing a priority of each of said plurality of said logical disk,
wherein said spare disk controller determines a number of said second physical disks for writing therein said recovered data, based on said priority of said logical disk involved with said failure.

6. A method for hot-swapping in a disk array system, comprising:
configuring a logical disk having a redundancy function from a plurality of first physical disks;
recovering data from said first physical disks by using said redundancy function upon occurring of a failure in said logical disk; and
writing said recovered data into at least two of said second physical disks in parallel.

7. The method according to claim 6, wherein said second physical disks have a writing data rate lower than a writing data rate of said first physical disks.

8. The method according to claim 7, wherein said writing step writes said recovered data into said second physical disks in parallel at a writing data rate higher than said writing data rate of said second physical disks.

9. The method according to claim 6, wherein said configuring step configures a plurality of said logical disk from said first physical disks.

10. The method according to claim 9, further comprising:
storing a priority of each of said plurality of said logical disk in a memory,
determining a number of said second physical disks for writing therein said recovered data, based on said priority of said logical disk involved with said failure.
